(19) United States
(12) Patent Application Publication
(10) Pub. No.: US 2026/0214872 A1
(43) Pub. Date: Jul. 23, 2026

(54) IONIZED WATER-BASED TRANSPARENT ELECTROMAGNETIC SHIELDING WINDOW SYSTEM

(71) Applicant: ELECTRONICS AND TELECOMMUNICATIONS RESEARCH INSTITUTE, Daejeon (KR)

(72) Inventors: Dae-Heon LEE, Daejeon (KR); Dae-Yeon KIM, Daejeon (KR); Up NAMKOONG, Daejeon (KR)

(21) Appl. No.: 19/172,214

(22) Filed: Apr. 7, 2025

(30) Foreign Application Priority Data
Jan. 23, 2025 (KR) 10-2025-0010353

(51) Int. Cl. H05K 9/00; E06B 5/10

(52) U.S. Cl. CPC H05K 9/0005; E06B 5/10

(57) ABSTRACT

Disclosed herein is an ionized water-based transparent electromagnetic shielding window system. The ionized water-based transparent electromagnetic shielding window system includes a transparent window, and an electromagnetic shielding unit accommodated in the transparent window, wherein the electromagnetic shielding unit includes a transparent electrode material coated on a surface of an inner accommodation space of the transparent window, and transparent ionized water filled in the inner accommodation space coated with the transparent electrode material.

### CROSS REFERENCE TO RELATED APPLICATION

This application claims the benefit of Korean Patent Application No. 10-2025-0010353, filed Jan. 23, 2025, which is hereby incorporated by reference in its entirety into this application.

### BACKGROUND OF THE INVENTION

### 1. Technical Field

The following embodiments relate to transparent electromagnetic shielding window system technology for improving internal visibility in electromagnetic shielding facilities such as electromagnetic shielding rooms, shielding racks, or small-sized enclosures.

### 2. Description of Related Art

A window system, which is one of components constituting a typical office environment, performs functions such as air circulation and light collection. However, due to deterioration in the performance of a transparent shielding material, it is not easy to employ a transparent window system in electromagnetic shielding rooms or electromagnetic (EMP) shielding facilities. Therefore, although a transparent material enabling an internal space to be monitored in environments such as a server rack or a server room, as well as a window system, is necessary, an opaque metal-based shielding material is used to satisfy protection performance.

Meanwhile, a transparent shielding material is manufactured using a transparent electrode. The transparent electrode is a functional thin-film electrode having electrical conductivity while transmitting light in a visible spectrum and is used for flat panel displays, touch panels, solar cells, and the like. Such a transparent shielding material is partially used for electromagnetic shielding, but is primarily used for electromagnetic compatibility (EMC)/electromagnetic interference (EMI), and thus it is difficult to predict high shielding effectiveness through the transparent shielding material.

The transparent electromagnetic shielding material is manufactured using metal oxides, carbon nanotubes, conductive polymers, and nanomeshes.

A representative of the metal oxide among the materials is Indium Tin Oxide (ITO) which is formed by substituting and solid-solubilizing tin in indium oxide. Most ITO is used as a transparent electrode material for glass substrate-based flat-panel displays and solar cells.

Such a carbon nanotube is a cylindrical carbon crystal that has a diameter ranging from 0.5 to 1 nm and that is composed of hexagons made up of six carbon atoms connected together, and possess characteristics such as high tensile strength and electrical conductivity

As a method for manufacturing a transparent material (electrode) using carbon nanotubes, the transparent material may be mainly manufactured by coating a transparent substrate with carbon nanotubes using an adhesive layer or by spraying carbon nanotubes onto a substrate in a spray coating manner. Technologies developed to date provide only low shielding effectiveness at the level of EMI protection measures.

Conductive polymers refer to materials having significantly high conductivity even if no metal is contained in organic compounds. Among the conductive polymers, PEDOT:PSS exhibits electrical properties approximate to those of amorphous ITO and excellent transmittance in a visible light spectrum, and enables processing in solution to meet the requirements as a next-generation transparent electrode.

Nanomeshes refer to metal grid-type transparent materials for increasing transmittance by forming a pattern on a metal electrode. When the metal electrode is finely patterned to form a nanomesh shape, high conductivity of metal itself is maintained without change while the transmittance of the metal electrode is increasing.

However, the development of the above-described transparent electromagnetic shielding window system is not easy for the following reasons.

First, it is significant to design and manufacture a shielding window system having transparency for monitoring of the inside of facilities and having broadband frequency shielding effectiveness. Further, because shielding effectiveness and transparency have a trade-off relationship, it is difficult to simultaneously improve both factors.

That is, the shielding effectiveness of shielding glass and films that utilize ITO having high transparency is about 20 to 30 dB, and mesh materials having a shielding effectiveness of about 60 to 70 dB show low transparency, and the mesh pattern thereof are visible with bared eyes, thus deteriorating user convenience.

### SUMMARY OF THE INVENTION

An embodiment is intended to provide a transparent electromagnetic shielding window system that achieves both high transparency and excellent electromagnetic shielding effectiveness.

An embodiment is intended to provide a transparent electromagnetic shielding window system that meets both indoor environment protection and aesthetic requirements.

In accordance with an aspect of the present disclosure, there is provided an ionized water-based transparent electromagnetic shielding window system, including a transparent window, and an electromagnetic shielding unit accommodated in the transparent window, wherein the electromagnetic shielding unit includes a transparent electrode material coated on a surface of an inner accommodation space of the transparent window, and transparent ionized water filled in the inner accommodation space coated with the transparent electrode material.

The transparent window may be made of an acrylic material.

The transparent window may include a window base in which a top-open cuboidal accommodation space is formed, and a window cap coupled to an upper portion of the window base in a state in which the electromagnetic shielding unit is accommodated in the cuboidal accommodation space.

The window base may include a predetermined groove formed in an upper portion thereof, and the window cap may include a protrusion that is formed on a lower portion thereof and that is to be fitted into the predetermined groove of the window base.

Conductive silicon may be attached between the predetermined groove of the window base and the protrusion of the window cap.

The transparent electrode material may be Indium Tin Oxide (ITO).

The transparent electrode material may be applied to a bottom surface and four wall surfaces of the cuboidal accommodation space of the window base, and a lower surface of the window cap that comes into contact with the cuboidal accommodation space of the window base.

The transparent window may be formed such that a transparent shielding film is attached to outer surfaces of the transparent window.

The transparent ionized water may include conductive powder and electrolyte, and conductivity of the transparent ionized water is equal to or greater than 3.5 S/m.

The transparent electromagnetic shielding window system may be configured such that a frame is coupled to an edge of the transparent window, and the frame is formed by two L-shaped frames joined together.

A conductive foam gasket may be filled between the transparent window and a frame.

In accordance with another aspect of the present disclosure, there is provided an ionized water-based transparent electromagnetic shielding window system, including an acrylic window base in which a top-open cuboidal accommodation space is formed, and an acrylic window cap coupled to an upper portion of the acrylic window base in a state in which an electromagnetic shielding unit is accommodated in the cuboidal accommodation space, wherein the electromagnetic shielding unit includes a transparent electrode material applied to a bottom surface and four wall surfaces of the cuboidal accommodation space of the acrylic window base and to a lower surface of the acrylic window cap that comes into contact with the accommodation space of the acrylic window base, and transparent ionized water filled in the accommodation space coated with the transparent electrode material.

The acrylic window base may include a predetermined groove formed in an upper portion thereof, and the acrylic window cap may include a protrusion that is formed on a lower portion thereof and that is to be fitted into the predetermined groove of the acrylic window base.

Conductive silicon may be attached between the predetermined groove of the acrylic window base and the protrusion of the acrylic window cap.

A transparent shielding film may be attached to outer surfaces of the acrylic window base and the acrylic window cap.

The transparent ionized water may include conductive powder and electrolyte, and conductivity of the transparent ionized water may be equal to or greater than 3.5 S/m.

Two L-shaped frames may be joined together at edges of the acrylic window base and the acrylic window cap.

A conductive foam gasket may be filled between the acrylic window base and the frame and between the acrylic window cap and the frame.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a view illustrating an example of an ionized water-based transparent electromagnetic shielding window system according to an embodiment;

FIG. 2 is a view illustrating an example of a sectional view of an ionized water-based transparent electromagnetic shielding window system, taken along line AA′ according to an embodiment;

FIG. 3 is a view illustrating an example in which the components of a transparent window are separated according to an embodiment;

FIG. 4 is a view illustrating an example of the result of shielding effectiveness simulation of an ionized water-based transparent electromagnetic shielding window system depending on the thickness of ionized water according to an embodiment;

FIGS. 5 and 6 are views illustrating an example of the frame coupling of an ionized water-based transparent electromagnetic shielding window system according to an embodiment; and

FIG. 7 is a view illustrating an example of a conductive foam gasket filled between an ionized water-based transparent electromagnetic shielding window system and a frame according to an embodiment.

### DESCRIPTION OF THE PREFERRED EMBODIMENTS

Advantages and features of the present disclosure and methods for achieving the same will be clarified with reference to embodiments described later in detail together with the accompanying drawings. However, the present disclosure is capable of being implemented in various forms, and is not limited to the embodiments described later, and these embodiments are provided so that this disclosure will be thorough and complete and will fully convey the scope of the present disclosure to those skilled in the art. The present disclosure should be defined by the scope of the accompanying claims. The same reference numerals are used to designate the same components throughout the specification.

It will be understood that, although the terms “first” and “second” may be used herein to describe various components, these components are not limited by these terms. These terms are only used to distinguish one component from another component. Therefore, it will be apparent that a first component, which will be described below, may alternatively be a second component without departing from the technical spirit of the present disclosure.

The terms used in the present specification are merely used to describe embodiments, and are not intended to limit the present disclosure. In the present specification, a singular expression includes the plural sense unless a description to the contrary is specifically made in context. It should be understood that the term “comprises” or “comprising” used in the specification implies that a described component or step is not intended to exclude the possibility that one or more other components or steps will be present or added.

Unless differently defined, all terms used in the present specification can be construed as having the same meanings as terms generally understood by those skilled in the art to which the present disclosure pertains. Further, terms defined in generally used dictionaries are not to be interpreted as having ideal or excessively formal meanings unless they are definitely defined in the present specification.

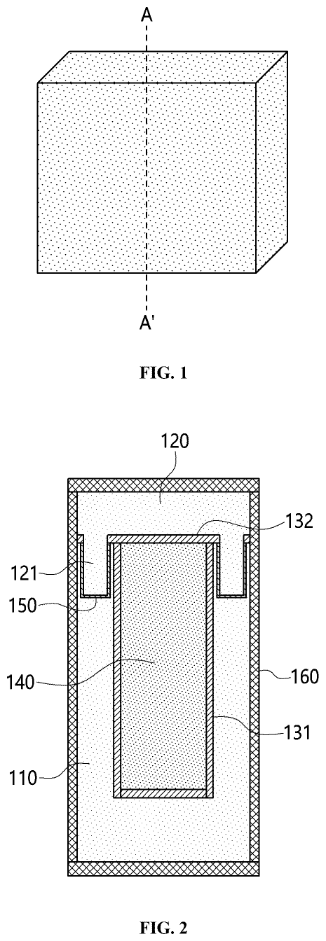

Hereinafter, an ionized water-based transparent electromagnetic shielding window system according to embodiments will be described in detail later with reference to FIGS. 1 to 7.

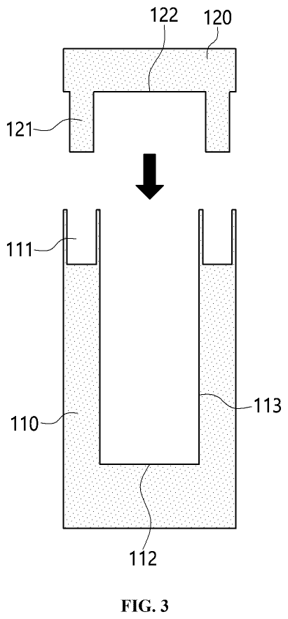

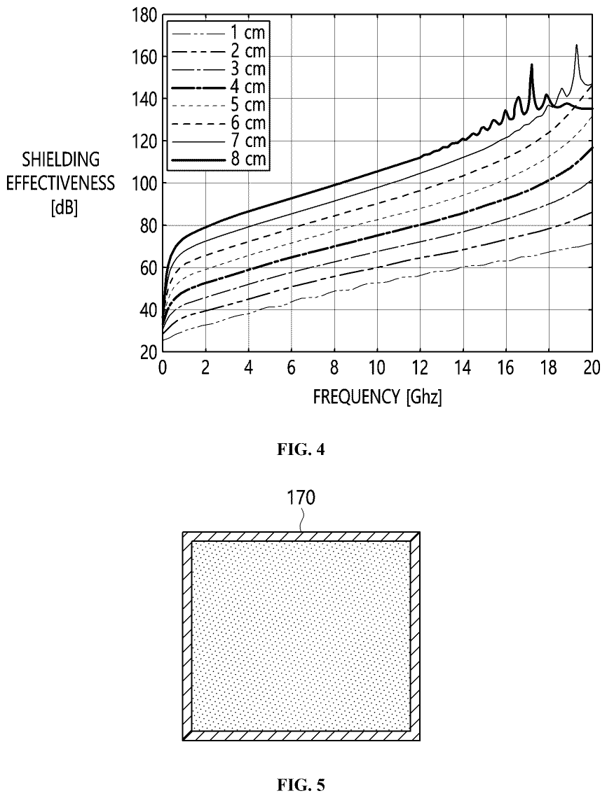

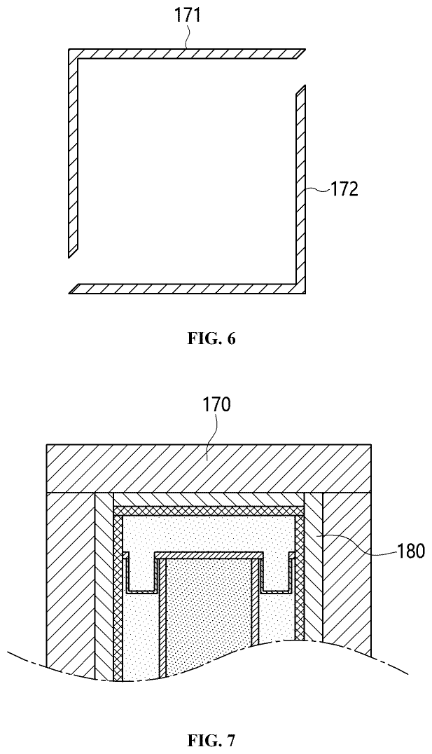

FIG. 1 is a view illustrating an example of an ionized water-based transparent electromagnetic shielding window system according to an embodiment, FIG. 2 is a view illustrating an example of a sectional view of an ionized water-based transparent electromagnetic shielding window system, taken along line AA′ according to an embodiment, FIG. 3 is a view illustrating an example in which the components of a transparent window are separated according to an embodiment, FIG. 4 is a view illustrating an example of the result of shielding effectiveness simulation of an ionized water-based transparent electromagnetic shielding window system depending on the thickness of ionized water according to an embodiment, FIGS. 5 and 6 are views illustrating an example of the frame coupling of an ionized water-based transparent electromagnetic shielding window system according to an embodiment, and FIG. 7 is a view illustrating an example of a conductive foam gasket filled between an ionized water-based transparent electromagnetic shielding window system and a frame according to an embodiment.

Referring to FIGS. 1 to 3, the ionized water-based transparent electromagnetic shielding window system may include transparent windows 110 and 120 and electronic shielding units 131, 132 and 140 accommodated in the transparent windows 110 and 120.

The transparent windows 110 and 120 according to an embodiment may be made of a transparent acrylic material.

Here, the transparent windows 110 and 120 may include a window base 110 in which a top-open cuboidal accommodation space is formed, and a window cap 120 coupled to the upper portion of the window base 110 in the state in which the electromagnetic shielding units are accommodated in the cuboidal accommodation space.

Here, the window base 110 may be manufactured in a U-shaped structure to ensure the stability of the window system. Further, the thickness of the window base 110 and the size of the inner accommodation space to be filled with ionized water may be determined in consideration of a window installation environment.

Meanwhile, referring to FIG. 3, a groove 111 may be formed in the upper portion of the window base 110, and a protrusion 121 to be fitted into the groove 111 of the window base 110 may be formed on the lower portion of the window cap 120.

Therefore, as illustrated in FIG. 2, after the electromagnetic shielding units 131, 132, and 140 are accommodated in the window base 110, the transparent windows may be assembled with the protrusion 121 fitted into the predetermined groove 111.

Here, conductive silicon 150 may be attached between the predetermined groove 111 of the window base 110 and the protrusion 121 of the window cap 120.

Such conductive silicon 150 may enable the groove 111 of the window base 110 and the protrusion 121 to be fastened and to be electrically connected to each other while providing a water-proof function.

Meanwhile, the electromagnetic shielding units according to an embodiment may include transparent electrode materials 131 and 132 coated on the surfaces of the inner accommodation space in the transparent windows 110 and 120, and transparent ionized water 140 filled in the inner accommodation space coated with the transparent electrode materials 131 and 132.

Here, the transparent ionized water 140 may contain conductive powder and electrolyte, and the conductivity thereof may be equal to or greater than 3.5 S/m.

Here, each of the transparent electrode materials 131 and 132 may be Indium Tin Oxide (ITO).

Here, the transparent electrode materials 131 and 132 may include transparent electrode materials 131 applied to the bottom surface and four wall surfaces of the cuboidal accommodation space of the window base 110 and a transparent electrode material 132 applied to the lower surface of the window cap 120 that comes into contact with the accommodation space of the window base 110.

Here, the transparent electrode materials 131 and 132 may be processed to be applied carefully to ensure continuity across all surfaces. Furthermore, for stable shielding effectiveness, the surface resistance of ITO-applied surfaces may be less than or equal to 30 Ω/□.

In this way, electrical leakage points may be minimized by applying ITO that is the transparent electrode material to six inner surfaces of the window system.

Also, as illustrated in FIG. 2, referring to the cross-section of the ionized water-based transparent electromagnetic shielding window system, a multi-layer shielding structure (ITO+ionized water+ITO) may be formed, and thus a stable shielding function may be enhanced.

That is, to overcome the difficulty of using the transparent electromagnetic shielding window system in shielding environments, such as actual shielding rooms or shielding racks, or using the same as interior materials due to low shielding effectiveness or insufficient transparency, the present embodiment may utilize a window system in which the electrical properties of water and ITO are combined with each other so as to achieve both high transparency and excellent electromagnetic shielding effectiveness.

According to the electromagnetic shielding theory, since electromagnetic waves are reflected to cause shielding due to the impedance difference between two media, and the dielectric constant of water is approximately 74 times greater than that of air, an electromagnetic shielding function based on the properties of water may be performed.

Therefore, in accordance with an embodiment, shielding effectiveness may be enhanced by combining the shielding effectiveness of ITO with the shielding effectiveness of water. That is, by means of the structure that utilizes the dielectric constants of ITO and water, the shielding effectiveness in a broad frequency band may be enhanced.

Further, the electromagnetic shielding units according to an embodiment may maintain high transmissivity of light while effectively blocking electromagnetic waves. Furthermore, water may be used as a principal shielding mechanism to provide an indoor environment safe to a human body, thus ensuring stability.

Furthermore, the electromagnetic shielding units according to an embodiment may enable electromagnetic shielding while maintaining transparency, thus providing a useful shielding window system that meets both electromagnetic shielding and interior elements through design elements suitable for the interior of office or residential spaces.

Furthermore, through the combination of acrylic and ITO, the transparent electromagnetic shielding window system may guarantee excellent thermal stability and durability, thus allowing for long-term use to enhance durability. In other words, the long-term use of the transparent electromagnetic shielding window system may be enabled by utilizing ITO, which does not react to water, and both acrylic and ITO may provide superior thermal stability and durability, thus resulting in lower maintenance costs.

Referring to FIG. 4, conductivity σ is derived by setting the surface resistance Rₛ of each wall surface, to which ITO is applied, to 30Ω/□ and applying an arbitrary acrylic thickness (t) of 5 mm to the following Equation (1):

$$σ = 1 / ( {R}_{s} \times t ) \qquad ( 1 )$$

When shielding effectiveness (SE) is calculated as the conductivity of the ionized water, calculated in this way, is fixed at 3.5 S/m and the thickness of ionized water changes within a range from 1 to 8 cm, it can be proven, as a result of the calculation, that, as the thickness increases, shielding effectiveness is enhanced in a broad frequency band less than or equal to 20 GHz, as shown in FIG. 4.

Meanwhile, referring back to FIG. 2, the transparent windows 110 and 120 may be configured such that a transparent shielding film 160 is attached to outer surfaces of the transparent windows 110 and 120. That is, to ground the ionized water-based transparent electromagnetic shielding window system according to an embodiment, a commercial transparent shielding film may be attached to six outer surfaces of the transparent windows that have been assembled.

Further, a frame 170 may be coupled to the edges of the transparent windows according to an embodiment, as shown in FIG. 5.

In this case, as illustrated in FIG. 6, the frame may be formed such that two L-shaped frames 171 and 172 are jointed together. That is, in order to install the wall surfaces of the windows, the edges of the windows may be reinforced using the two L-shaped frames.

Furthermore, in the ionized water-based transparent electromagnetic shielding window system according to an embodiment, as illustrated in FIG. 7, a conductive foam gasket 180 may be filled between the transparent windows and the frame 170. That is, the conductive foam gasket 180 may be inserted between the frame and the transparent windows to enable electrical connection to be made without electromagnetic leakage.

According to embodiments, there can be provided a transparent electromagnetic shielding window system that achieves both high transparency and excellent electromagnetic shielding effectiveness. That is, shielding effectiveness can be enhanced by utilizing ionized water and ITO, which have high conductivity and permittivity, while transparency can be enhanced by utilizing the properties of transparent acrylic, ITO, and water. This enables internal conditions to be monitored through each transparent window, which is expected to promote the adoption of protective facilities.

According to embodiments, there can be provided a transparent electromagnetic shielding window system that meets both indoor environment protection and aesthetic requirements. Since the shielding mechanism of ionized water is used as a key factor, the window system may be made of an eco-friendly and human-safe material, thus providing a safe indoor environment. Moreover, because the window system is transparent and enables electromagnetic shielding, it may be utilized as a design element suitable for interior applications, such as office or residential spaces and shielding racks.

Although the embodiment of the present disclosure has been disclosed, those skilled in the art will appreciate that the present disclosure can be implemented as other concrete forms, without departing from the scope and spirit of the disclosure as disclosed in the accompanying claims. Therefore, it should be understood that the exemplary embodiment is only for illustrative purpose and do not limit the scope of the present disclosure.

What is claimed is:

1. An ionized water-based transparent electromagnetic shielding window system, comprising:
a transparent window; and
an electromagnetic shielding unit accommodated in the transparent window,
wherein the electromagnetic shielding unit comprises:
a transparent electrode material coated on a surface of an inner accommodation space of the transparent window; and
transparent ionized water filled in the inner accommodation space coated with the transparent electrode material.

2. The ionized water-based transparent electromagnetic shielding window system of claim 1, wherein the transparent window is made of an acrylic material.

3. The ionized water-based transparent electromagnetic shielding window system of claim 1, wherein the transparent window comprises:
a window base in which a top-open cuboidal accommodation space is formed; and
a window cap coupled to an upper portion of the window base in a state in which the electromagnetic shielding unit is accommodated in the cuboidal accommodation space.

4. The ionized water-based transparent electromagnetic shielding window system of claim 3, wherein:
the window base includes a predetermined groove formed in an upper portion thereof, and
the window cap includes a protrusion that is formed on a lower portion thereof and that is to be fitted into the predetermined groove of the window base.

5. The ionized water-based transparent electromagnetic shielding window system of claim 4, wherein conductive silicon is attached between the predetermined groove of the window base and the protrusion of the window cap.

6. The ionized water-based transparent electromagnetic shielding window system of claim 1, wherein the transparent electrode material is Indium Tin Oxide (ITO).

7. The ionized water-based transparent electromagnetic shielding window system of claim 3, wherein the transparent electrode material is applied to:
a bottom surface and four wall surfaces of the cuboidal accommodation space of the window base; and
a lower surface of the window cap that comes into contact with the cuboidal accommodation space of the window base.

8. The ionized water-based transparent electromagnetic shielding window system of claim 1, wherein the transparent window is formed such that a transparent shielding film is attached to outer surfaces of the transparent window.

9. The ionized water-based transparent electromagnetic shielding window system of claim 1, wherein the transparent ionized water includes conductive powder and electrolyte, and conductivity of the transparent ionized water is equal to or greater than 3.5 S/m.

10. The ionized water-based transparent electromagnetic shielding window system of claim 1, wherein the transparent electromagnetic shielding window system is configured such that:
a frame is coupled to an edge of the transparent window, and
the frame is formed by two L-shaped frames joined together.

11. The ionized water-based transparent electromagnetic shielding window system of claim 10, wherein a conductive foam gasket is filled between the transparent window and a frame.

12. An ionized water-based transparent electromagnetic shielding window system, comprising:
an acrylic window base in which a top-open cuboidal accommodation space is formed; and
an acrylic window cap coupled to an upper portion of the acrylic window base in a state in which an electromagnetic shielding unit is accommodated in the cuboidal accommodation space,
wherein the electromagnetic shielding unit comprises:
a transparent electrode material applied to a bottom surface and four wall surfaces of the cuboidal accommodation space of the acrylic window base and to a lower surface of the acrylic window cap that comes into contact with the accommodation space of the acrylic window base; and
transparent ionized water filled in the accommodation space coated with the transparent electrode material.

13. The ionized water-based transparent electromagnetic shielding window system of claim 12, wherein:
the acrylic window base includes a predetermined groove formed in an upper portion thereof, and
the acrylic window cap includes a protrusion that is formed on a lower portion thereof and that is to be fitted into the predetermined groove of the acrylic window base.

14. The ionized water-based transparent electromagnetic shielding window system of claim 13, wherein conductive silicon is attached between the predetermined groove of the acrylic window base and the protrusion of the acrylic window cap.

15. The ionized water-based transparent electromagnetic shielding window system of claim 12, wherein a transparent shielding film is attached to outer surfaces of the acrylic window base and the acrylic window cap.

16. The ionized water-based transparent electromagnetic shielding window system of claim 12, wherein the transparent ionized water includes conductive powder and electrolyte, and conductivity of the transparent ionized water is equal to or greater than 3.5 S/m.

17. The ionized water-based transparent electromagnetic shielding window system of claim 12, wherein two L-shaped frames are joined together at edges of the acrylic window base and the acrylic window cap.

18. The ionized water-based transparent electromagnetic shielding window system of claim 17, wherein a conductive foam gasket is filled between the acrylic window base and the frame and between the acrylic window cap and the frame.
